(19) United States
(12) Patent Application Publication
(10) Pub. No.: US 2015/0122531 A1
(43) Pub. Date: May 7, 2015

(54) STRAIN GAUGE

(71) Applicant: Carestream Health, Inc., Rochester, NY (US)

(72) Inventors: Robert J. Monson, Roseville, MN (US); Andrew T. Fried, Woodbury, MN (US)

(21) Appl. No.: 14/503,466

(22) Filed: Oct. 1, 2014

Related U.S. Application Data
(60) Provisional application No. 61/898,637, filed on Nov. 1, 2013.

(51) Int. Cl. H05K 1/02; H05K 1/09

(52) U.S. Cl. CPC H05K 1/0274; H05K 1/09
USPC 174/253

(57) ABSTRACT

An article comprising a conductive film comprising conductive structures, and a first resistive element patterned into a first portion of the conductive film. In at least some cases, the conductive structures may comprise nanostructures, such as, for example, nanowires. Silver nanowires are exemplary conductive structures. In some useful applications, the first resistive element may be part of a circuit, such as, for example, a Wheatstone bridge.

### CROSS REFERENCE TO RELATED APPLICATIONS

This application claims the benefit of U.S. Provisional Patent Application No. 61/898,637, filed Nov. 1, 2013, entitled STRAIN GAUGE, which is hereby incorporated by reference in its entirety.

### BACKGROUND

A strain gauge may be integrated into a thin-film circuit. U.S. Pat. No. 4,522,067 to Burger et al. Such strain gauges may be in the form of a touch sensor. EP 2657812A2 to Graphene Square. Strain gauges may be attached to any structural element in which strain on the structural element is to be measured. For example, a strain gauge may be used to measure a load of an occupant seated on a search in a vehicle. U.S. Pat. No. 7,555,960 to Nakano et al.

### SUMMARY

At least a first embodiment provides an article comprising a conductive film comprising conductive structures, and a first resistive element patterned into a first portion of the conductive film. In at least some cases, the conductive structures may comprise nanostructures, such as, for example, nanowires. Silver nanowires are exemplary conductive structures. In some useful applications, the first resistive element may be part of a Wheatstone bridge.

In at least some such embodiments, the first portion of the conductive film is capable of deflection. In some cases, the article may comprise at least one second portion of the conductive film that is less flexible than the first portion. Such a second portion may, in some cases, comprise at least one second resistive element patterned therein. In some useful applications, the at least one second resistive element may be part of a Wheatstone bridge.

More generally, the article may comprise at least one second resistive element that may or may not be part of such a second portion of the conductive film, where the first resistive element and the at least one second resistive element are part of a Wheatstone bridge.

At least a second embodiment provides an electrical circuit comprising a Wheatstone bridge, the Wheatstone bridge comprising at least one first resistive element, where the at least one first resistive element is patterned into a first portion of a conductive film comprising conductive structures. In at least some cases, the conductive structures may comprise nanostructures, such as, for example, nanowires. Silver nanowires are exemplary conductive structures. In some useful applications, the first resistive element may be part of a Wheatstone bridge.

In at least some such embodiments, the first portion of the conductive film is capable of deflection. In some cases, the article may comprise at least one second portion of the conductive film that is less flexible than the first portion. Such a second portion may, in some cases, comprise at least one second resistive element patterned therein. In some useful applications, the at least one second resistive element may be part of a Wheatstone bridge.

In at least some such embodiments, the electrical circuit may further comprise at least another resistive element that is not patterned into the conductive film. For example, such a resistive element may be part of a Wheatstone bridge comprising the at least one first resistive element.

### DESCRIPTION OF FIGURES

FIG. 1 shows a Wheatstone bridge circuit diagram.

FIG. 2 shows a strain gauge that may be integrated into a transparent film that is arranged in a Wheatstone bridge configuration, such as that shown, for example, in FIG. 1.

### DESCRIPTION

All publications, patents, and patent documents referred to in this document are incorporated by reference herein in their entirety, as though individually incorporated by reference.

U.S. Provisional Patent Application No. 61/898,637, filed Nov. 1, 2013, entitled STRAIN GAUGE, is hereby incorporated by reference in its entirety.

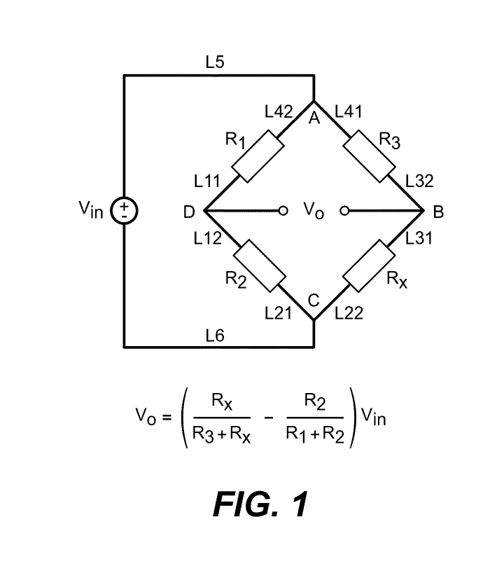

FIG. 1 depicts a circuit diagram of a Wheatstone bridge. Such a bridge has four resistors R1, R2, R3, and Rx, each of which has two electrical terminals. It is to be understood that each of the four resistors may each independently be a single resistive element or a plurality of resistive elements exhibiting overall resistances equivalent to R1, R2, R3, and Rx, respectively. The resistors are interconnected via conductive resistor connections L11, L12, L21, L22, L31, L32, L41, and L42. L11 connects the first terminal of resistor R1 to a node D. L12 connects the first terminal of resistor R2 to the node D. L21 connects the second terminal of resistor R2 to a node C. L22 connects the first terminal of resistor Rx to the node C. L31 connects the second terminal of resistor Rx to a node B. L32 connects the first terminal of resistor R3 to the node B. L41 connects the second terminal of resistor R3 to a node A. L42 connects the second terminal of resistor R1 to the node A. Supply voltage Vin may be provided across nodes A and C, as shown in FIG. 1, or alternatively across nodes B and D. Voltage Vo may be measured across nodes B and D, as shown in FIG. 1, or alternatively across nodes A and C in the case where the supply voltage Vin is provided across nodes B and D. In the case where the resistances of the conductive resistor connections are negligible, the following relationship holds:

$${V}_{o} = ( \frac{{R}_{x}}{{R}_{3} + {R}_{x}} - \frac{{R}_{2}}{{R}_{1} + {R}_{2}} ) \cdot {V}_{in} \qquad ( 1 )$$

In the case where resistances R1, R2, and R3 are known, the value of an unknown resistance Rx may be inferred from knowledge of Vo and Vin.

In some embodiments, the resistors R1, R2, R3, and Rx of the Wheatstone bridge form a strain gauge. A strain gauge is a device that may be used to measure strain on an object. The strain gauge may be attached to an object in which strain is to be measured. As the object is subjected to strain, the strain gauge and its pattern may be deformed from its original shape or size or deflected from its original position, causing its electrical resistance Rx to change. This change in electrical resistance, which may be measured using a Wheatstone bridge, is related to the strain by the gauge factor. A strain gauge takes advantage of the relationship between the physical property of electrical conductance and the conductor's geometry. The strain gauge that is in the form of a transparent conductive film may comprise any of the various electrical conductors. When the strain gage is stretched within the limits of its elasticity without breaking or permanent deformation, the electrical conductor may become narrower and longer, which increases its electrical resistance end-to-end. When the strain gauge is compressed without buckling, the electrical conductor may broaden and shorten, which decreases its electrical resistance end-to-end. The strain gauge may also be used to measure force, pressure, travel, weight, or acceleration, as is known to one skilled in the art.

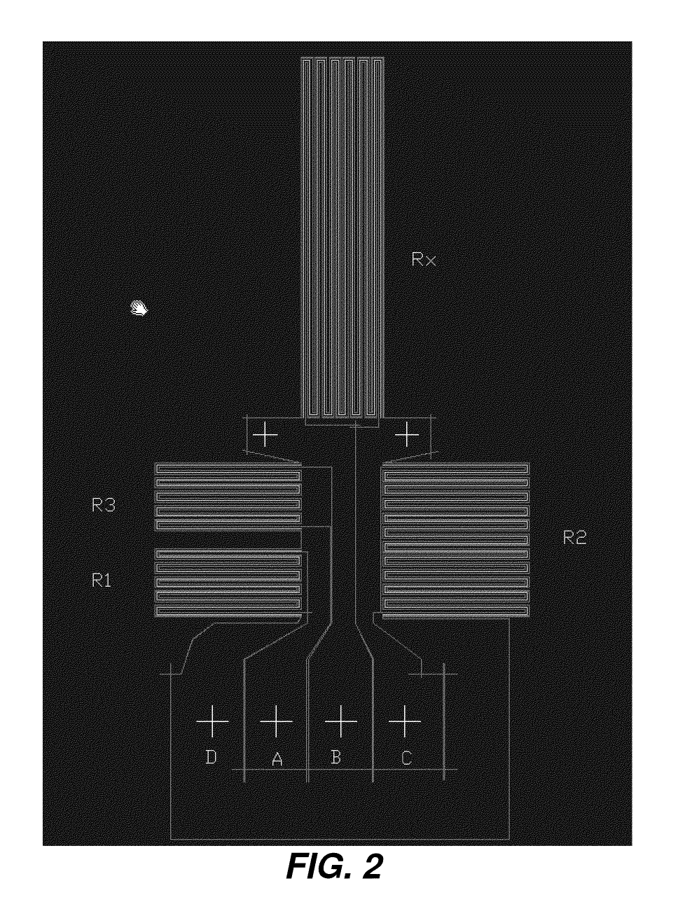

FIG. 2 shows a strain gauge that may be patterned into a transparent film that is arranged in a Wheatstone bridge configuration, such as that shown, for example, in FIG. 1. As shown, the circuit has four resistors R1, R2, R3, and Rx. The conductivity path within each of the resistors follows a serpentine path. The pattern may be formed through various techniques, include, for example, laser patterning, photolithography, screen printing, chemical etching, and the like. The resistors R1, R2, R3, and Rx are interconnected electrically via resistor connections (not labeled in FIG. 2), which may be short, low-impedance connections. From these resistor connections, connection tracks (not labeled) may lead to nodes, sometimes referred to as connection points, D, A, B, and C. Supply voltage Vin (not shown in FIG. 2) may be supplied across nodes A and C or alternatively across nodes B and D. Voltage Vo (not shown in FIG. 2) may be measured across nodes B and D or alternatively across nodes A and C in the case where the supply voltage Vin is supplied across nodes B and D.

At least some of the resistive elements of the Wheatstone bridge may be patterned into a transparent conductive film. In some embodiments, all of the resistive elements are so patterned. It will be understood that in preferred embodiments, at least resistance Rx of the bridge is patterned into the transparent conductive film. In some embodiments, at least some, if not the entire, portion of the film may be deformable or deflectable. In this application, a structural element that is “deformable” is able to be changed temporarily or permanently due to applied force or change in temperature. Such changes may include a change in shape or size of an object. In this application, a structural element that is “deflectable” is able to be displaced or moved from its original position when subjected to a load or force. A structural element may be deformed or deflected thermally or mechanically. In some embodiments, the film may be deflectable at a first end, for example, near resistor Rx, relative to the second end that is opposite to the first end, for example, near connection points D, A, B, and C. In such cases, the second end may be attached to devices, such as a voltage supplier or a measurement device.

It will be understood that in cases where resistance Rx is patterned into the transparent conductive film and one or more of resistances R1, R2, and R3 is also so patterned, that the resistance Rx will preferably be positioned into a portion of the film that is more deflectable (i.e., less rigid) than the portions(s) into which any of the other resistances is patterned. The other portion(s) may be less deflectable (i.e., more rigid) owing to differences in physical properties of the film itself, or by virtue of the rigidity of neighboring members to which those portion(s) may be fastened.

Examples of electrical conductors include microstructures or nanostructures. Microstructures and nanostructures are defined according to the length of their shortest dimensions. The shortest dimension of the nanostructure is sized between 1 nm and 100 nm. The shortest dimension of the microstructure is sized between 0.1 μm to 100 μm. Conductive nanostructures may include, for example, metal nanostructures. In some embodiments, the conductive nanostructures may be metal nanowires, carbon nanotubes, metal meshes, transparent conductive oxide, and graphene. In some embodiments, the conductive nanostructures may be metal nanowires, such as, for example, silver nanowires. The transparent conductive films comprising electrical conductors may be patterned to introduce regions of higher resistivity within the transparent conductive film, leaving other regions as lower resistivity regions. The transparent conductive film may comprise several layers made from the same or different polymers. Such polymers include, for example, polyethylene terephthalate (PET) and cellulose acetate butyrate (CAB).

### EXEMPLARY EMBODIMENTS

U.S. Provisional Patent Application No. 61/898,637, filed Nov. 1, 2013, entitled STRAIN GAUGE, which is hereby incorporated by reference in its entirety, disclosed at least the following 30 non-limiting exemplary embodiments:

A. An article comprising:
a conductive film comprising conductive structures, and
a first resistive element patterned into a first portion of the conductive film.
   B. The article according to embodiment A, wherein the conductive structures comprise nanostructures.
   C. The article according to embodiment A, wherein the conductive structures comprise nanowires.
   D. The article according to embodiment A, wherein the conductive structures comprise silver nanowires.
   E. The article according to embodiment A, wherein the at least one first resistive element is part of a Wheatstone bridge.
   F. The article according to embodiment A, wherein the first portion of the conductive film is capable of deflection.
   G. The article according to embodiment F, further comprising at least a second portion of the conductive film that is less flexible than the first portion.
   H. The article according to embodiment G, wherein the at least one second portion of the conductive film comprises at least a second resistive element.
   J. The article according to embodiment H, wherein the at least one second resistive element is part of a Wheatstone bridge.
   K. The article according to embodiment A, further comprising at least one second resistive element, wherein the first resistive element and the at least one second resistive element are part of a Wheatstone bridge.
   L. An electrical circuit comprising a Wheatstone bridge, the Wheatstone bridge comprising at least one first resistive element,

wherein the at least one first resistive element is patterned into a first portion of a conductive film comprising conductive structures.

M. The electrical circuit according to embodiment L, wherein the conductive structures comprise nano structures.
N. The electrical circuit according to embodiment L, wherein the conductive structures comprise nanowires.
P. The electrical circuit according to embodiment L, wherein the conductive structures comprise silver nanowires.
Q. The electrical circuit according to embodiment L, wherein the first portion of the conductive film is capable of deflection.
R. The electrical circuit according to embodiment Q, wherein the conductive film comprises at least a second portion hat is less flexible than the first portion.
S. The electrical circuit according to embodiment R, wherein the at least one second portion of the conductive film comprises at least a second resistive element.
T. The electrical circuit according to embodiment S, wherein the at least one second resistive element is part of a Wheatstone bridge.
U. The electrical circuit according to any of embodiments L-T further comprising at least another resistive element that is not patterned into the conductive film.
V. The electrical circuit according to embodiment U, wherein the at least another resistive element is part of the Wheatstone bridge.
W. A method comprising:
deflecting a first deformable portion of a conductive film comprising conductive structures, the first portion comprising at a first resistive element,
wherein the first resistive element exhibits a first resistance prior to the deflection and exhibits a second resistance different from the first resistance during the deflection.
   X. The method according to embodiment W, wherein the conductive structures comprise nanostructures.
   Y. The method according to embodiment W, wherein the conductive structures comprise nanowires.
   Z. The method according to embodiment W, wherein the conductive structures comprise silver nanowires.
   AA. The method according to embodiment W, wherein the first resistive element is part of a Wheatstone bridge.
   AB. The method according to embodiment W, wherein the conductive film comprises at least a second portion hat is less flexible than the first portion.
   AC. The method according to embodiment AB, wherein the at least one second portion of the conductive film comprises at least a second resistive element.
   AD. The method according to embodiment AC, wherein the at least one second resistive element is part of a Wheatstone bridge.
   AE. The method according to any of embodiments AA or AD, wherein the Wheatstone bridge comprises at least another resistive element that is not patterned into the conductive film.
   AF. The method according to embodiment W, wherein deflecting the first deformable region comprises applying a force to the first deformable region or causing a change in temperature in the first deformable region.

The invention has been described in detail with reference to specific embodiments, but it will be understood that variations and modifications can be effected within the spirit and scope of the invention. The presently disclosed embodiments are therefore considered in all respects to be illustrative and not restrictive. The scope of the invention is indicated by the attached claims, and all changes that come within the meaning and range of equivalents thereof are intended to be embraced therein.

What is claimed:

1. An article comprising:
a conductive film comprising conductive structures, and
a first resistive element patterned into a first portion of the conductive film.

2. The article according to claim 1, wherein the conductive structures comprise nanostructures.

3. The article according to claim 1, wherein the conductive structures comprise nanowires.

4. The article according to claim 1, wherein the conductive structures comprise silver nanowires.

5. The article according to claim 1, wherein the at least one first resistive element is part of a Wheatstone bridge.

6. The article according to claim 1, wherein the first portion of the conductive film is capable of deflection.

7. The article according to claim 6, further comprising at least a second portion of the conductive film that is less flexible than the first portion.

8. The article according to claim 7, wherein the at least one second portion of the conductive film comprises at least a second resistive element patterned therein.

9. The article according to claim 8, wherein the at least one second resistive element is part of a Wheatstone bridge.

10. The article according to claim 1, further comprising at least one second resistive element, wherein the first resistive element and the at least one second resistive element are part of a Wheatstone bridge.

11. An electrical circuit comprising a Wheatstone bridge, the Wheatstone bridge comprising at least one first resistive element,
wherein the at least one first resistive element is patterned into a first portion of a conductive film comprising conductive structures.

12. The electrical circuit according to claim 11, wherein the conductive structures comprise nano structures.

13. The electrical circuit according to claim 11, wherein the conductive structures comprise nanowires.

14. The electrical circuit according to claim 11, wherein the conductive structures comprise silver nanowires.

15. The electrical circuit according to claim 11, wherein the first portion of the conductive film is capable of deflection.

16. The electrical circuit according to claim 15, wherein the conductive film comprises at least a second portion hat is less flexible than the first portion.

17. The electrical circuit according to embodiment 16, wherein the at least one second portion of the conductive film comprises at least a second resistive element patterned therein.

18. The electrical circuit according to claim 17, wherein the at least one second resistive element is part of a Wheatstone bridge.

19. The electrical circuit according to claim 11 further comprising at least another resistive element that is not patterned into the conductive film.

20. The electrical circuit according to claim 19, wherein the at least another resistive element is part of the Wheatstone bridge.
